(19) United States
(12) Patent Application Publication
(10) Pub. No.: US 2026/0313283 A1
(43) Pub. Date: Oct. 8, 2026

(54) EARPHONE

(71) Applicant: VIVO MOBILE COMMUNICATION CO., LTD., Dongguan (CN)

(72) Inventor: Xianjing JIAN, Dongguan (CN)

(73) Assignee: VIVO MOBILE COMMUNICATION CO., LTD., Dongguan (CN)

(21) Appl. No.: 19/460,640

(22) Filed: Jan. 27, 2026

Related U.S. Application Data
(63) Continuation of application No. PCT/CN2024/107174, filed on Jul. 24, 2024.

(30) Foreign Application Priority Data
Jul. 28, 2023 (CN) 202310946950.2

(51) Int. Cl. H04R 1/10; H05K 1/02; H05K 1/14

(52) U.S. Cl. CPC H04R 1/1041; H04R 1/1016; H05K 1/0215; H05K 1/0243; H05K 1/147; H04R 2420/07; H05K 2201/10098

(57) ABSTRACT

This application provides an earphone. The earphone includes a main circuit board, a radiator, and an extended ground plane, where the radiator is disposed on a first surface of the main circuit board; the extended ground plane is disposed on a second surface of the main circuit board, and shares a common ground with the main circuit board; and the first surface is a surface away from a wearer, and the second surface is a surface facing the wearer.

### CROSS-REFERENCE TO RELATED APPLICATIONS

This application is a continuation application of PCT International Application No. PCT/CN2024/107174 filed on Jul. 24, 2024, which claims priority to Chinese Patent Application No. 202310946950.2, entitled "EARPHONE" and filed on Jul. 28, 2023, which is incorporated herein by reference in its entirety.

### TECHNICAL FIELD

This application relates to the technical field of electronic products, and specifically, to an earphone.

### BACKGROUND

True wireless stereo (TWS) earphones are beloved by consumers since their launch. The TWS earphone does not require a wired connection, and two earpieces form a stereo system through Bluetooth, delivering impressive performance both in terms of convenience and audio quality. Nowadays, the TWS earphone is the most popular earphone on the market besides a conventional earphone. However, due to absorption and blocking of a signal by a human head, radiation efficiency of an antenna in the earphone is low.

### SUMMARY

This application provides an earphone.

Embodiments of this application provide an earphone, including: a main circuit board, a radiator, and an extended ground plane, where

the radiator is disposed on a first surface of the main circuit board;

the extended ground plane is disposed on a second surface of the main circuit board, and shares a common ground with the main circuit board; and

the first surface is a surface away from a wearer, and the second surface is a surface facing the wearer.

### BRIEF DESCRIPTION OF THE DRAWINGS

FIG. 1 is a schematic structural diagram 1 of an earphone according to an embodiment of this application;

FIG. 2 is a schematic structural diagram 2 of an earphone according to an embodiment of this application;

FIG. 3 is a schematic structural diagram 3 of an earphone according to an embodiment of this application;

FIG. 4 is a schematic structural diagram 4 of an earphone according to an embodiment of this application;

FIG. 5 is a schematic structural diagram 5 of an earphone according to an embodiment of this application;

FIG. 6 is a schematic structural diagram of a main circuit board according to an embodiment of this application;

FIG. 7 is a diagram of comparison between radiation efficiency of a loop antenna and radiation efficiency of a conventional planar inverted-F antenna according to an embodiment of this application;

FIG. 8 is a schematic diagram of a flowing state of a current generated in a loop antenna when the loop antenna is in an operating state according to an embodiment of this application;

FIG. 9 is a schematic diagram of electric field distribution near an earphone in a case that an extended ground plane is not disposed in the earphone;

FIG. 10 is a schematic diagram of electric field distribution near an earphone after an extended ground plane is disposed in the earphone;

FIG. 11 is a comparison diagram of human body loss of antennas with and without an extended ground plane;

FIG. 12 is a comparison diagram of radiation efficiency of antennas with and without an extended ground plane;

FIG. 13 is a schematic cross-sectional view of a main circuit board according to an embodiment of this application; and

FIG. 14 is a schematic cross-sectional view of a flexible circuit board according to an embodiment of this application.

### DETAILED DESCRIPTION

The following clearly describes technical solutions in the embodiments of this application with reference to the accompanying drawings in the embodiments of this application. Apparently, the described embodiments are some of the embodiments of this application rather than all of the embodiments. All other embodiments derived by a person of ordinary skill in the art based on the embodiments of this application shall fall within the protection scope of this application.

In the specification and claims of this application, the terms "first", "second", and the like are used to distinguish similar objects, but are not used to describe a specific sequence or order. It may be understood that the data used in such a way is interchangeable in proper circumstances, so that the embodiments of this application described herein can be implemented in other sequences than the sequence illustrated or described herein, and the objects distinguished through "first", "second", and the like are generally of a same type and the number of the objects are not limited, for example, there may be one or more first objects. In addition, "and/or" in the specification and the claims represents at least one of the connected objects, and a character "/" used herein generally indicates an "or" relationship between associated objects.

An earphone according to the embodiments of this application is described in detail below with reference to the accompanying drawings through specific embodiments and application scenarios thereof.

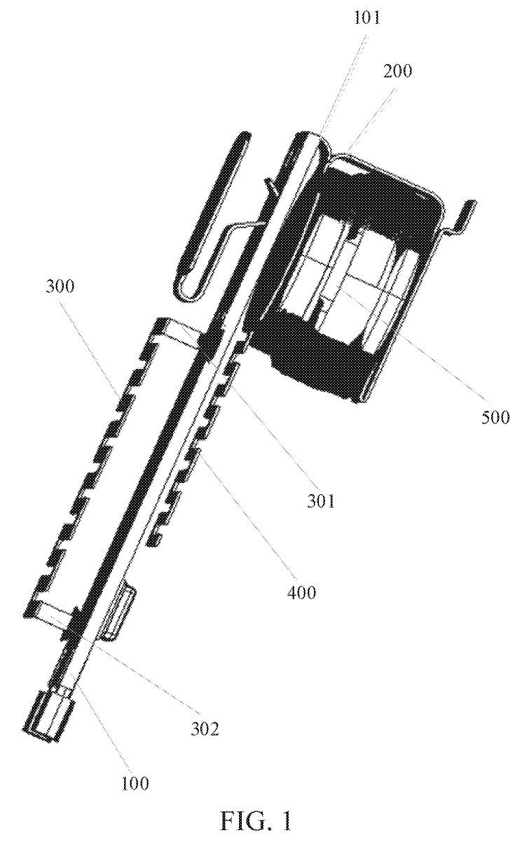

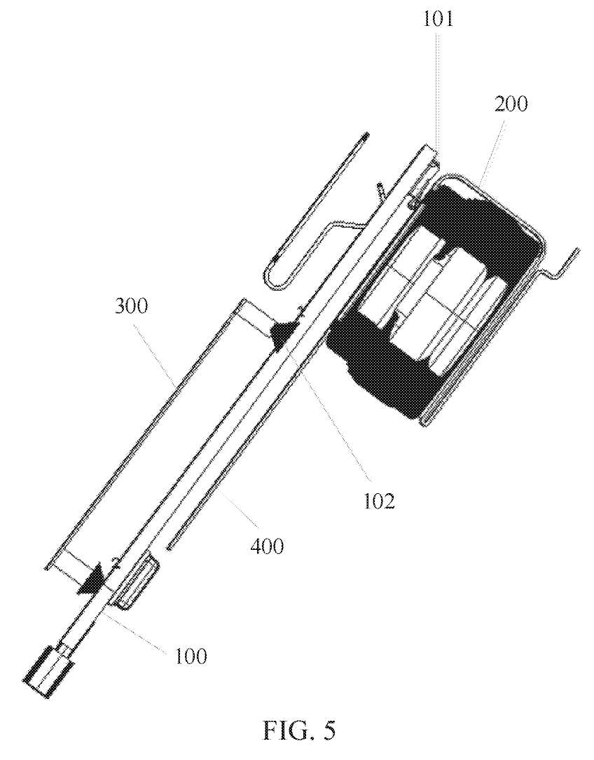

FIGS. 1 to 5 are schematic structural diagrams of an earphone according to an embodiment of this application. The earphone includes a main circuit board 100, a radiator 300, and an extended ground plane 400, where the radiator 300 is disposed on a first surface 107 of the main circuit board 100; the extended ground plane 400 is disposed on a second surface 108 of the main circuit board 100, and shares a common ground with the main circuit board 100; and the first surface 107 is a surface away from a wearer, and the second surface 108 is a surface facing the wearer.

It may be understood that, the foregoing radiator 300 is a radiator of an antenna in the earphone. The radiator 300 may be electrically connected to the main circuit board. In this way, a feed signal may be fed to the radiator 300 by the main circuit board 100. In addition, the radiator 300 may be further grounded through a ground layer in the main circuit board 100, thereby forming an antenna structure. In this way, when the main circuit board 100 feeds the feed signal to the radiator 300, a current is formed in the radiator 300, and the current in the radiator 300 may flow to the ground layer of the main circuit board 100.

That the extended ground plane 400 shares the common ground with the main circuit board 100 means that the ground layer in the main circuit board 100 is electrically connected to the extended ground plane 400.

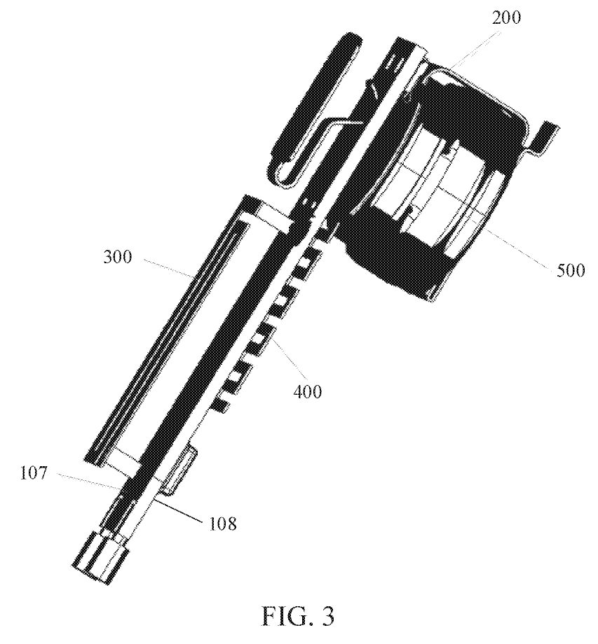

That the first surface 107 is the surface away from the wearer specifically means that the first surface 107 is a surface of the main circuit board 100 away from the wearer when the earphone is worn. In other words, when the earphone is worn, the first surface 107 is a surface of the main circuit board 100 that faces away from the wearer. Specifically, referring to FIGS. 3 to 5, the earphone may include an ear cup 500, and the ear cup 500 may include an in-ear bud. When the earphone is worn, a user inserts the ear bud into an ear. In this case, the first surface 107 of the main circuit board 100 faces away from a face of the wearer, and the second surface 108 of the main circuit board 100 faces the face of the wearer.

The earphone may be one earpiece of a Bluetooth earphone, for example, may be one earpiece with an antenna in a TWS earphone.

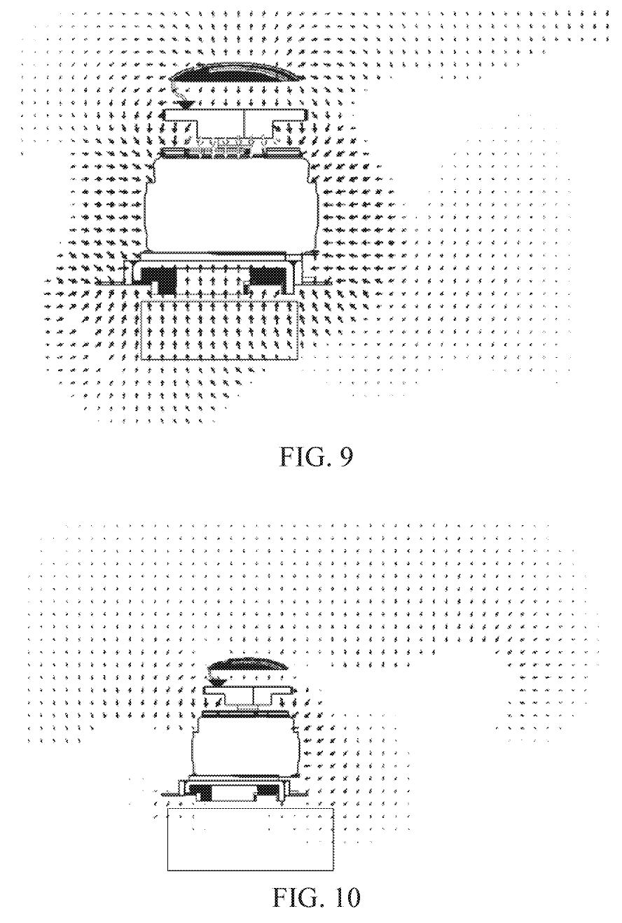

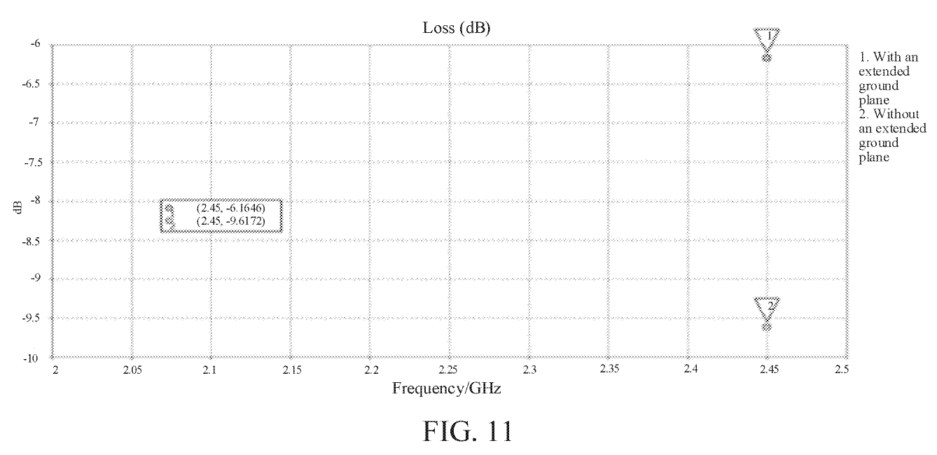

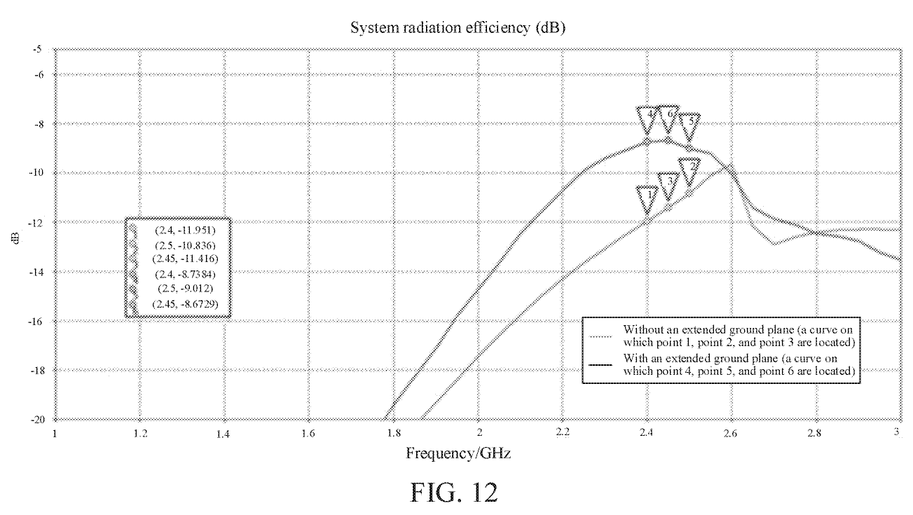

Referring to FIGS. 9 and 10, FIG. 10 is a schematic diagram of electric field distribution near an earphone after the extended ground plane 400 is disposed in the earphone, where an area indicated by a rectangular box in FIG. 10 is an electric field entering a human body. FIG. 9 is a schematic diagram of electric field distribution near an earphone in a case that the extended ground plane 400 is not disposed in the earphone, where an area indicated by a rectangular box in FIG. 9 is an electric field entering the human body. It can be learned from FIGS. 9 and 10 that, in a case that the extended ground plane 400 is not disposed, most of the electric field enters the human body, while after the extended ground plane 400 is added, the electric field distribution is changed, which can apparently reduce the electric field entering the human body, thereby further reducing loss of radiation performance caused by the human body. FIG. 11 is a comparison diagram of human body loss of antennas with and without the extended ground plane 400. It can be learned from FIG. 11 that, the additional disposition of the extended ground plane 400 may reduce human body loss of 3 dB. FIG. 12 is a comparison diagram of radiation efficiency of antennas with and without the extended ground plane 400. It can be learned from FIG. 12 that, the radiation efficiency of the antenna with the extended ground plane 400 is 3 dB higher, thereby greatly improving head phantom efficiency of the earphone and improving user experience.

In this implementation, the extended ground plane 400 shares the common ground with the main circuit board 100. In this way, a current flowing from the radiator 300 to the ground layer of the main circuit board 100 can flow further to the extended ground plane 400. This helps to extend a path length of a current in an antenna inside the earphone, thereby improving radiation efficiency of the antenna. In addition, the radiator 300 is disposed on the first surface 107 of the main circuit board 100, the extended ground plane 400 is disposed on the second surface 108 of the main circuit board 100, the first surface 107 is the surface away from the wearer, and the second surface 108 is the surface facing the wearer. In this way, when the earphone is worn, because the main circuit board 100 and the extended ground plane 400 are closer to the wearer than the radiator 300, this helps to further increase a distance between the radiator 300 and the human body, thereby reducing head phantom loss and further improving the radiation efficiency of the antenna.

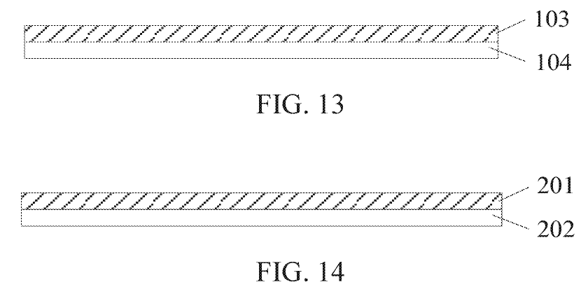

Optionally, FIG. 13 is a schematic cross-sectional view of a main circuit board according to an embodiment of this application; and FIG. 14 is a schematic cross-sectional view of a flexible circuit board according to an embodiment of this application. As shown in FIGS. 13 and 14, the earphone further includes a flexible circuit board 200, and the main circuit board 100 includes a first signal layer 103 and a first ground layer 104, where the flexible circuit board 200 includes a second ground layer 202, the first ground layer 104 is electrically connected to the second ground layer 202, and the extended ground plane 400 is electrically connected to the second ground layer 202; and

a first terminal 301 of the radiator 300 is electrically connected to a radio frequency transceiver circuitry 102 in the first signal layer 103, and a second terminal 302 of the radiator 300 is electrically connected to the first ground layer 104, to form a loop antenna.

The foregoing radio frequency transceiver circuitry 102 may form a feed source (namely, a radio frequency signal source) of the loop antenna, the first terminal 301 of the radiator 300 forms a feed point, and the first signal layer 103 is electrically connected to the feed point through the radio frequency transceiver circuitry 102, to feed the feed signal to the radiator 300.

The foregoing first signal layer 103 and the foregoing first ground layer 104 may be stacked. Alternatively, the first signal layer 103 and the first ground layer 104 may be located on a same plane. For example, a hollow area may be provided in the first ground layer 104, and the first signal layer 103 may be disposed in the hollow area.

The foregoing flexible circuit board 200 may be a flexible circuit board 200 disposed for mounting a relevant electrical component in the earphone. The foregoing first ground layer 104 forms a ground plane of the main circuit board 100, the foregoing second ground layer 202 forms a ground plane of the flexible circuit board 200, and the foregoing extended ground plane 400 is a ground plane additionally disposed for extending the current path length of the antenna in the earphone.

It may be understood that, the radiator 300 may be bent to form a radiator of the loop antenna.

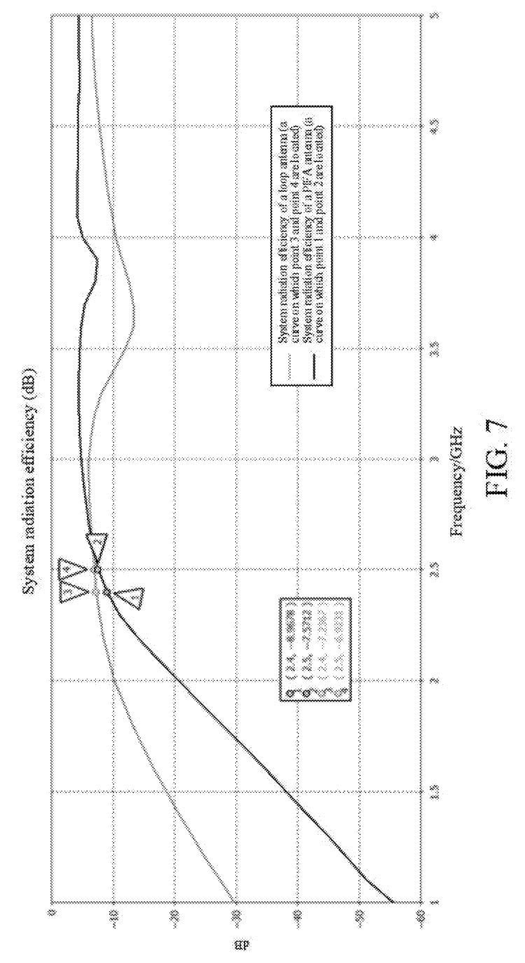

Specifically, the loop antenna is a self-balancing antenna. Therefore, compared with a conventional antenna, a current of the loop antenna is mainly concentrated in an antenna branch, and the current of the loop antenna on the ground plane is weak. However, the conventional antenna has strong current distribution on the ground plane. FIG. 7 is a diagram of comparison between radiation efficiency of a loop antenna and radiation efficiency of a conventional planar inverted-F antenna. It can be learned from FIG. 7 that, the radiation efficiency of the loop antenna is 1 dB higher than the radiation efficiency of the conventional PIFA (Planar Inverted F-shaped Antenna).

In this implementation, the first ground layer 104 is electrically connected to the second ground layer 202, and the extended ground plane 400 is electrically connected to the second ground layer 202. In this way, a current transmitted from the radiator 300 to the first ground layer 104 may flow to the second ground layer 202 through the first ground layer 104, and then flow to the extended ground plane 400 through the second ground layer 202. This helps to extend the path length of the current in the antenna, thereby improving the radiation efficiency of the antenna. In addition, the loop antenna is formed in the earphone, and compared with the conventional antenna (for example, an inverted-F antenna (IFA) or a monopole antenna), a current of the loop antenna is mainly concentrated in an antenna branch, the current of the loop antenna on the ground plane is weak, and the ground plane in the earphone is closer to the human body than the radiator. Therefore, compared with disposing the conventional antenna in the earphone, forming the loop antenna in the earphone has lower head phantom loss, thereby helping to further improve the radiation efficiency of the antenna in the earphone.

Optionally, the first ground layer 104 further includes a ground terminal 101, and the first ground layer 104 is electrically connected to the second ground layer 202 through the ground terminal 101, where the ground terminal 101, the first terminal 301 of the radiator 300, and the second terminal 302 of the radiator 300 are disposed at intervals in a length direction of the circuit board; and the first terminal 301 of the radiator 300 is located between the ground terminal 101 and the second terminal 302 of the radiator 300.

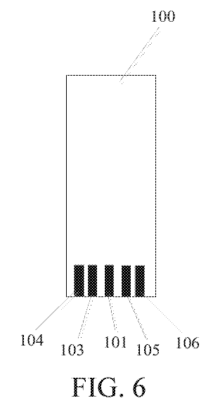

The foregoing ground terminal 101 may be a first ground pin (a first GND pin). A circuit board in a conventional earphone generally includes four pins for connecting a speaker and a battery, and the four pins are respectively: Spk+, Spk–, Bat+, and Bat–, where Spk+ is labeled 104 in FIG. 6, Spk– is labeled 103 in FIG. 6, Bat+ is labeled 105 in FIG. 6, and Bat– is labeled 106 in FIG. 6. Referring to FIG. 6, in this embodiment of this application, the first GND pin may be disposed in addition to the four pins, and the first GND pin may be disposed between the two Spk pins and the two Bat pins. Certainly, the first GDN pin may alternatively be disposed on either side of the foregoing four pins. The first GDN pin is additionally disposed for ease of connecting the first ground layer 104 and the second ground layer 202. A second GDN pin may be disposed on the second ground layer 202, and the second ground layer 202 may be electrically connected to the extended ground plane 400 through the second GDN pin.

It may be understood that, the flexible circuit board 200 may further include a second signal layer 201. The second signal layer 201 and the second ground layer 202 may be stacked, or the second signal layer 201 and the second ground layer 202 may be disposed on a same plane. The second signal layer 201 may be electrically connected to the foregoing Spk+, Spk–, Bat+, Bat–, and the first GDN pin simultaneously. It may be understood that, the first GDN pin is electrically connected to the second ground layer 202 through the second signal layer 201.

In addition, the earphone further includes a speaker and a battery, and at least one of the speaker or the battery is electrically connected to the second signal layer 201. For example, the speaker and the battery are separately electrically connected to the second signal layer 201. That is, the flexible circuit board 200 is a flexible circuit board 200 configured to mount the speaker and the battery in the earphone. In this way, the flexible circuit board 200 in the earphone is reused, and a connection position between the flexible circuit board 200 and the main circuit board 100 is changed (that is, a position of the ground terminal 101 is changed, that is, a cable outlet position of the flexible circuit board 200 is changed), to extend a current path length of the antenna.

Referring to FIG. 1, a part of current formed in the radiator 300 may enter the first ground layer 104 from the second terminal 302 of the radiator 300, and because the first terminal 301 of the radiator 300 is located between the ground terminal 101 and the second terminal 302 of the radiator 300, after entering the first ground layer 104, the current needs to be transmitted from one end of the first ground layer 104 to the other end to reach the ground terminal 101, and then enter the second ground layer 202 through the ground terminal 101, so that the current path length of the antenna in the earphone can be further increased.

Optionally, the ground terminal 101 is located at an end portion of the first ground layer 104 in a length direction.

The flexible circuit board 200 may include a conductive elastic piece corresponding to the ground terminal 101, and the flexible circuit board 200 is electrically connected to the ground terminal 101 through the conductive elastic piece, or an electrical connection between the flexible circuit board 200 and the ground terminal 101 may be established by direct soldering (Hotbar). Referring to FIG. 1, the ground terminal 101 is located at an end of the main circuit board 100 close to the ear cup 500.

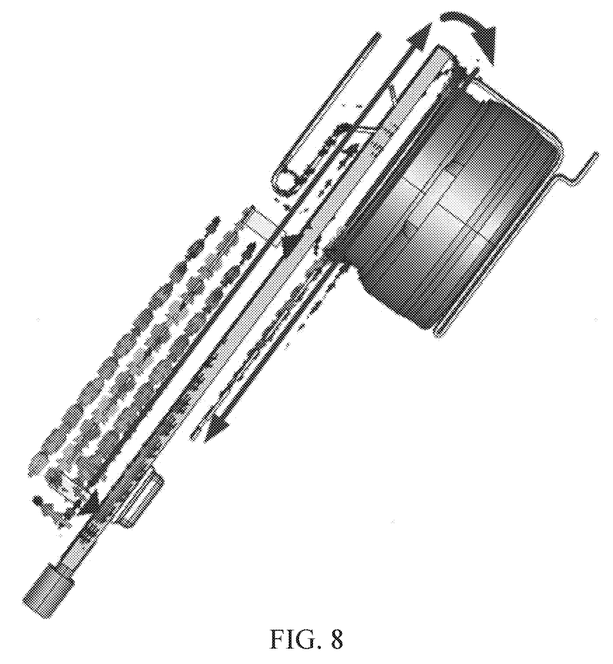

In this implementation, the ground terminal 101 is disposed at the end portion of the first ground layer 104 in the length direction. In this way, a transmission length of the current in the first ground layer 104 that enters the first ground layer 104 may be further extended, which helps to further increase the current path length of the antenna in the earphone. FIG. 8 is a schematic diagram of a flowing state of a current generated in a loop antenna when the loop antenna is in an operating state according to an embodiment of this application. Specifically, a flowing path of a current entering a first ground layer 104 from a second terminal 302 of a radiator 300 is a path indicated by an arrow in FIG. 8. In other words, the current is first transmitted from one end of the first ground layer 104 in a length direction to the other end, is transmitted from a top portion of the first ground layer 104 to a flexible circuit board 200, and is then transmitted from the flexible circuit board 200 to the extended ground plane 400 and transmitted from one end of the extended ground plane 400 to the other end.

Optionally, the extended ground plane 400 is in a shape of a strip plate, and a length of the extended ground plane 400 matches a length of the first ground layer 104.

Specifically, that the length of the extended ground plane 400 matches the length of the first ground layer 104 may mean that the length of the extended ground plane 400 may be equal to the length of the first ground layer 104. Alternatively, that the length of the extended ground plane 400 matches the length of the first ground layer 104 may mean that the length of the extended ground plane 400 is slightly less than the length of the first ground layer 104.

In addition, a ratio of a width of the extended ground plane 400 to a width of the first ground layer 104 ranges from 0.5 to 1. Specifically, when the ratio of the width of the extended ground plane 400 to the width of the first ground layer 104 is less than 0.5, effectiveness of the extended ground plane 400 is reduced. Therefore, making the ratio of the width of the extended ground plane 400 to the width of the first ground layer 104 range from 0.5 to 1 helps to avoid the reduction of the effectiveness of the extended ground plane 400. In addition, the length of the extended ground plane 400 is made to be slightly less than or equal to the length of the first ground layer 104, and the ratio of the width of the extended ground plane 400 to the width of the first ground layer 104 is made to range from 0.5 to 1. In this way, a size of the extended ground plane 400 can be prevented from exceeding a size range of the main circuit board 100, so that an orthographic projection of the extended ground plane 400 onto the main circuit board 100 can be located within the main circuit board 100. In this way, the extended ground plane 400 can be additionally disposed without enlarging a size of the earphone.

Optionally, the earphone further includes a housing, where the housing includes an ear cup 500 and an ear stem, and the ear cup 500 is connected to the ear stem, where the main circuit board 100 is disposed in the housing, the radiator 300 is disposed in the ear stem, and the flexible circuit board 200 is disposed in the ear cup 500; and

the extended ground plane 400 is disposed in the ear stem, and the extended ground plane 400 is attached to an inner wall of the ear stem; or the extended ground plane 400 is disposed in the ear cup 500, and the extended ground plane 400 is attached to an inner wall of the ear cup 500.

It may be understood that, a part of the main circuit board 100 may be located in the ear cup 500, and additionally, another part of the main circuit board 100 may be located in the ear stem.

The ear cup 500 is an ellipsoidal outer shell for mounting an ear bud in the earphone. Correspondingly, the ear stem is a rod-shaped outer shell connected to the ear cup 500, and a relevant control button in the earphone may be disposed on the ear stem.

In this implementation, the extended ground plane 400 is attached to the inner wall of the ear stem, or the extended ground plane 400 is attached to the inner wall of the ear cup 500, to mount and fix the extended ground plane 400.

Optionally, the radiator 300 is located on a side of the first ground layer 104 facing away from the ear cup 500.

In this implementation, because a side of first ground layer 104 facing the ear cup 500 is closer to the human body, making the radiator 300 located on the side of the first ground layer 104 facing away from the ear cup 500 helps to further increase a distance between the radiator 300 and the human body, so that head phantom loss may be further reduced.

Optionally, the extended ground plane 400 is a serpentine board.

Referring to FIG. 3, when the extended ground plane 400 is attached to the inner wall of the ear cup 500, setting the extended ground plane 400 in a serpentine shape may help to further reduce the size of the extended ground plane 400, thereby further reducing a mounting space inside the earphone required for the extended ground plane 400.

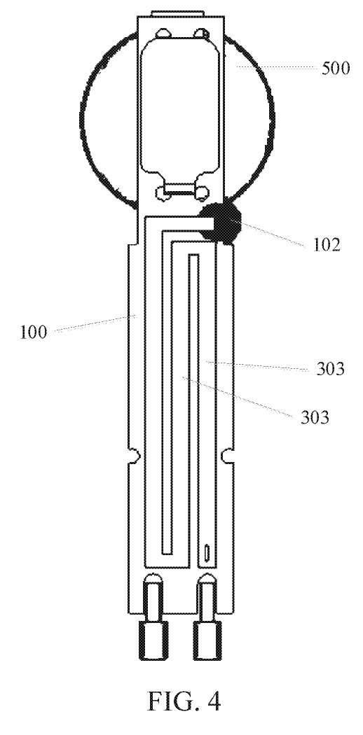

Optionally, referring to FIGS. 3 and 4, the radiator 300 includes at least three strip-shaped segments 303, the at least three strip-shaped segments 303 are disposed at intervals in a width direction of the main circuit board 100, and the at least three strip-shaped segments 303 are connected end to end sequentially to form a serpentine radiator.

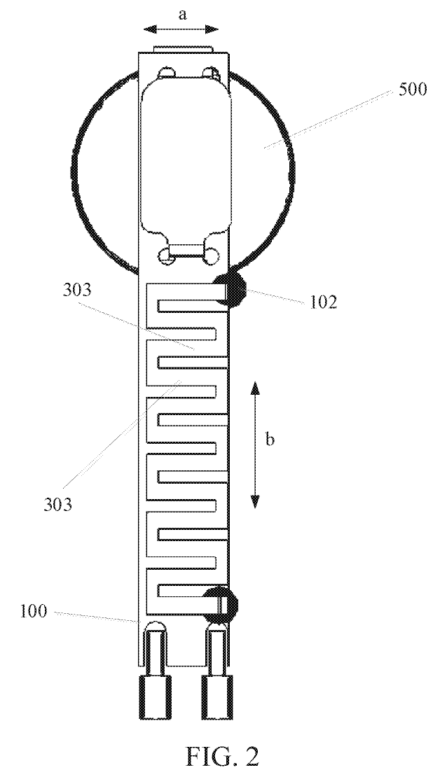

Alternatively, referring to FIGS. 1 and 2, the radiator 300 includes at least three strip-shaped segments 303, the at least three strip-shaped segments 303 are disposed at intervals in a length direction of the main circuit board 100, and the at least three strip-shaped segments 303 are connected end to end sequentially to form a serpentine radiator.

Referring to FIG. 2, a double-headed arrow a in FIG. 2 indicates the width direction of the main circuit board 100, and a double-headed arrow b in FIG. 2 indicates the length direction of the main circuit board 100.

In this implementation, by winding the radiator 300 into a serpentine coiled structure, a length of the radiator 300 may be further increased, thereby improving a signal radiation effect or a signal reception effect of the radiator 300.

Optionally, the earphone further includes a housing, a speaker, and a battery, where the housing includes an ear cup 500 and an ear stem, and the ear cup 500 is connected to the ear stem, where the main circuit board 100 is disposed in the housing, the radiator 300 is disposed in the ear stem, and the flexible circuit board 200 is disposed in the ear cup 500; the extended ground plane 400 is disposed in the ear cup 500, and the extended ground plane 400 is attached to an inner wall of the ear cup 500; and the flexible circuit board 200 further includes a second signal layer 201, and at least one of the speaker or the battery is electrically connected to the second signal layer 201.

In this implementation, the flexible circuit board 200 in the earphone is reused, and a connection position between the flexible circuit board 200 and the main circuit board 100 is changed, to extend the current path length of the antenna.

Another embodiment of this application provides a true wireless stereo earphone, including a first earphone and a second earphone, where at least one of the first earphone or the second earphone is the earphone described in the foregoing embodiments.

In this implementation, because at least one of the first earphone or the second earphone in the true wireless stereo earphone is the earphone described in the foregoing embodiments, the true wireless stereo earphone can implement each process of the earphone in the foregoing embodiments, and the same beneficial effects can be achieved. To avoid repetition, details are not described herein again.

The embodiments of this application are described above with reference to the accompanying drawings, but this application is not limited to the foregoing specific embodiments, which are merely illustrative rather than limited. Under the inspiration of this application, a person of ordinary skill in the art can make many forms without departing from the scope of this application and the protection of the claims, all of which fall within the protection of this application.

1. An earphone, comprising: a main circuit board, a radiator, and an extended ground plane, wherein
the radiator is disposed on a first surface of the main circuit board;
the extended ground plane is disposed on a second surface of the main circuit board, and shares a common ground with the main circuit board; and
the first surface is a surface away from a wearer, and the second surface is a surface facing the wearer.

2. The earphone according to claim 1, wherein the earphone further comprises a flexible circuit board, and the main circuit board comprises a first signal layer and a first ground layer, wherein the flexible circuit board comprises a second ground layer, the first ground layer is electrically connected to the second ground layer, and the extended ground plane is electrically connected to the second ground layer; and
a first terminal of the radiator is electrically connected to a radio frequency transceiver circuitry in the first signal layer, and a second terminal of the radiator is electrically connected to the first ground layer, to form a loop antenna.

3. The earphone according to claim 2, wherein the first ground layer further comprises a ground terminal, and the first ground layer is electrically connected to the second ground layer through the ground terminal, wherein the ground terminal, the first terminal of the radiator, and the second terminal of the radiator are disposed at intervals in a length direction of the circuit board; and the first terminal of the radiator is located between the ground terminal and the second terminal of the radiator.

4. The earphone according to claim 3, wherein the ground terminal is located at an end portion of the first ground layer in a length direction.

5. The earphone according to claim 2, wherein the extended ground plane is in a shape of a strip plate, and a length of the extended ground plane matches a length of the first ground layer.

6. The earphone according to claim 5, wherein a ratio of a width of the extended ground plane to a width of the first ground layer ranges from 0.5 to 1.

7. The earphone according to claim 1, further comprising: a housing, wherein the housing comprises an ear cup and an ear stem, and the ear cup is connected to the ear stem, wherein the main circuit board is disposed in the housing, and the radiator is disposed in the ear stem; and
the extended ground plane is disposed in the ear stem, and the extended ground plane is attached to an inner wall of the ear stem.

8. The earphone according to claim 7, wherein the extended ground plane is a serpentine board.

9. The earphone according to claim 1, wherein the radiator comprises at least three strip-shaped segments, the at least three strip-shaped segments are disposed at intervals in a width direction of the main circuit board, and the at least three strip-shaped segments are connected end to end sequentially to form a serpentine radiator; or
the radiator comprises at least three strip-shaped segments, the at least three strip-shaped segments are disposed at intervals in a length direction of the main circuit board, and the at least three strip-shaped segments are connected end to end sequentially to form a serpentine radiator.

10. The earphone according to claim 2, further comprising: a housing, a speaker, and a battery, wherein the housing comprises an ear cup and an ear stem, and the ear cup is connected to the ear stem; the main circuit board is disposed in the housing, the radiator is disposed in the ear stem, the extended ground plane is disposed in the ear cup, and the extended ground plane is attached to an inner wall of the ear cup; and the flexible circuit board further comprises a second signal layer, and at least one of the speaker or the battery is electrically connected to the second signal layer.
